(19) United States
(12) Patent Application Publication
(10) Pub. No.: US 2005/0233532 A1
(43) Pub. Date: Oct. 20, 2005

(54) Method of forming sidewall spacers

(76) Inventors: Markus Lenski, Dresden (DE); Falk Graetsch, Dresden (DE); Carsten Reichel, Freiberg (DE); Christoph Schwan, Gebhardshain (DE); Helmut Bierstedt, Dresden (DE); Thorsten Kammler, Ottendorf-Okrilla (DE); Martin Mazur, Pulsnitz (DE)

Correspondence Address: WILLIAMS, MORGAN & AMERSON, P.C., 10333 RICHMOND, SUITE 1100, HOUSTON, TX, 77042, US

(21) Appl. No.: 11/039,084

(22) Filed: Jan. 19, 2005

(30) Foreign Application Priority Data
Mar. 31, 2004 (DE) 10 2004 015 864.9

(51) Int. Cl. H01L 29/45; H01L 31/111; H01L 29/74; H01L 21/337; H01L 21/336

(52) U.S. Cl. 438/301; 438/303

(57) ABSTRACT

The present invention allows the formation of sidewall spacers adjacent a feature on a substrate without there being an undesirable erosion of the feature. The feature is covered by one or more protective layers. A layer of a spacer material is deposited over the feature and etched anisotropically. An etchant used in the anisotropic etching is adapted to selectively remove the spacer material, whereas the one or more protective layers are substantially not affected by the etchant. Thus, the one or more protective layers protect the feature from being exposed to the etchant.

### BACKGROUND OF THE INVENTION

1. Field of the Invention

The present invention relates to the field of manufacturing of semiconductor devices, and, more particularly, to the formation of sidewall spacers.

2. Description of the Related Art

Integrated circuits comprise a large number of individual circuit elements, such as transistors, capacitors, resistors, etc. These elements are connected internally to form complex circuits, such as memory devices, logic devices and microprocessors. An improvement in the performance of integrated circuits requires a reduction of feature sizes. In addition to an increase in the speed of operation due to reduced signal propagation times, reduced feature sizes allow an increase in the number of functional elements in the circuit in order to extend its functionality.

FIG. 1c shows a schematic cross-sectional view of a field effect transistor 100 according to the state of the art. A substrate 101 comprises an active region 102. Shallow trench isolations 103, 104 isolate the active region 102 from neighboring circuit elements. A gate electrode 106 having side surfaces 114, 115 and a top surface 116 is formed over the substrate 101 and isolated from the substrate 101 by a gate insulation layer 105. A protective layer 108 is provided over a surface of the substrate 101 and the side surfaces 114, 115 of the gate electrode 106. The gate electrode 106 is flanked by sidewall spacers 117, 118.

Additionally, the field effect transistor 100 comprises an extended source region 109, an extended drain region 110, a source region 112 and a drain region 113. A portion of the extended source region 109, which is denoted as “source extension,” and a portion of the extended drain region 110, denoted as “drain extension,” extend below the sidewall spacers 117, 118 and are adjacent the gate electrode 106.

A method of forming the field effect transistor 100 is described with reference to FIGS. 1a-1c. FIG. 1a shows a schematic cross-sectional view of the field effect transistor 100 in a first stage of the manufacturing process.

First, the trench isolations 103, 104 and the active region 102 are formed in the substrate 101. Then, the gate insulation layer 105 and the gate electrode 116 are formed over the substrate 102. The top surface 116 of the gate electrode 106 is covered by a coating layer 107. These structures can be formed using advanced techniques of ion implantation, deposition, oxidation and photolithography.

In particular, the gate electrode 106 is formed by patterning a layer of gate electrode material, e.g., polysilicon, over the substrate 101 and the gate insulation layer 105 using known photolithography and etching techniques. Photolithography, which is well known to persons skilled in the art, comprises depositing a photoresist layer (not shown) over the substrate 101 and exposing the photoresist layer. In order to avoid adverse effects resulting from an interference between incident light and light reflected from the layer of gate electrode material, an anti-reflective coating layer 107 may be formed above the layer of gate electrode material. The thickness of the coating layer 107 may be adapted such that light reflected from the surface of the coating layer 107 interferes destructively with light reflected from an interface between the coating layer 107 and the surface of the layer of gate electrode material. Thus, the reflectivity of the layer of material and the coating layer 107 is effectively reduced. After the layer of photoresist is patterned using known photolithography techniques to define a mask, known etching processes are performed on the exposed portions of the coating layer 107 and the layer of gate electrode material to define the gate electrode 156.

After the formation of the gate electrode 106 covered with the coating layer 107, the protective layer 108 is formed over the substrate and the side surfaces 114, 115 of the gate electrode 106. This may be done by means of thermal oxidation of a portion of the gate electrode and a portion of the substrate 101. Since the top surface 116 of the gate electrode 106 is covered by the coating layer 107 during the thermal oxidation, the protective layer 108 does not extend over the top surface 106. Then, the coating layer 107 is etched away.

A later stage of the manufacturing process is shown in FIG. 1b. The extended source region 109 and the extended drain region 110 are formed by implanting ions of a dopant material into the substrate 101 adjacent the gate electrode 106. Parts of the substrate 101 outside the field effect transistor 100 that are not to be doped are covered by a layer of photoresist (not shown) that blocks and absorbs the ions.

Following implantation, the sidewall spacers 117, 118 are formed. A layer 111 of a spacer material is conformally deposited over the substrate 101, e.g., by means of chemical vapor deposition (CVD). In conformal deposition, a local thickness of the deposited layer is substantially independent of a local slope of the surface on which it is deposited. In particular, the layer 111 has a substantially equal thickness on horizontal surfaces such as the surface of the substrate 101 and the top surface 116 of the gate electrode 106, and on vertical surfaces such as the side surfaces 114, 115 of the gate electrode 106.

The layer of spacer material 111 is etched anisotropically. In anisotropic etching, an etch rate in a vertical direction is greater than an etch rate in a horizontal direction. Therefore fore, portions of the layer of spacer material 111 whose surface is substantially horizontal, such as portions of the layer 111 on the top surface 116 of the gate electrode 106 or on the surface of the substrate 101, are removed more quickly than inclined portions of the layer 111. In particular, portions of the layer 111 whose surface is substantially horizontal are removed more quickly than portions of the layer 111 whose surface is substantially vertical, such as, e.g., portions of the layer 111 on the side surfaces 114, 115 of the gate electrode 106.

The etching of the layer 111 of the spacer material is stopped upon removal of the portions of the layer 111 having a horizontal surface. Due to the slower removal of portions of the layer 111 having a vertical surface, residues of these portions remain on the substrate and form the sidewall spacers 117, 118 adjacent the gate electrode 106.

Following the formation of the sidewall spacers 117, 118, the source region 112 and the drain region 113 are formed by implantation of ions of a dopant material. A schematic cross-sectional view of the field effect transistor 100 after the formation of the source region 112 and the drain region 113 is shown in FIG. 1c.

Finally, an annealing step may be performed to activate dopants in the active region 102, the extended source region 109, the extended drain region 110, the source region 112 and the drain region 113.

A problem of the prior art method of forming a field effect transistor is that, in etching the layer 111 of spacer material, the gate electrode 106 is exposed to the etchant, which leads to an erosion of the gate electrode 106, as indicated schematically by the jagged appearance of the top surface of the gate electrode 106 in FIG. 1c. The erosion of the gate electrode 106 may adversely affect the stability of the formation of the field effect transistor 100, since the shape of the gate electrode 106 is altered in an uncontrolled manner.

In view of this problem, a need exists for techniques that allow the manufacturing of a field effect transistor, wherein erosion of the gate electrode during the formation of the sidewall spacers is reduced.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to an illustrative embodiment of the present invention, a method of forming sidewall spacers comprises forming a feature over a substrate. The feature has a side surface and a top surface. The top surface is covered by a first protective layer and a coating layer. A second protective layer is formed over the side surface and the substrate. The coating layer is removed. A layer of a spacer material is deposited conformally over the side surface, the top surface and the substrate. The layer of spacer material is etched anisotropically.

According to another illustrative embodiment of the present invention, a method of forming sidewall spacers comprises forming a feature over a substrate. The feature has a side surface and a top surface. The top surface is covered by a coating layer. A first protective layer is formed over the side surface and the substrate. The coating layer is removed. A second protective layer is formed over the side surface, the top surface and the substrate. A layer of a spacer material is deposited conformally over the side surface, the top surface and the substrate. The layer of spacer material is etched anisotropically.

### BRIEF DESCRIPTION OF THE DRAWINGS

The invention may be understood by reference to the following description taken in conjunction with the accompanying drawings, in which like reference numerals identify like elements, and in which:

FIGS. 1a-1c show schematic cross-sectional views of a field effect transistor in stages of a manufacturing process according to the state of the art;

FIGS. 2a-2d show schematic cross-sectional views of a field effect transistor in stages of a manufacturing process according to an embodiment of the present invention; and

FIGS. 3a-3c show schematic cross-sectional views of a field effect transistor in stages of a manufacturing process according to another embodiment of the present invention.

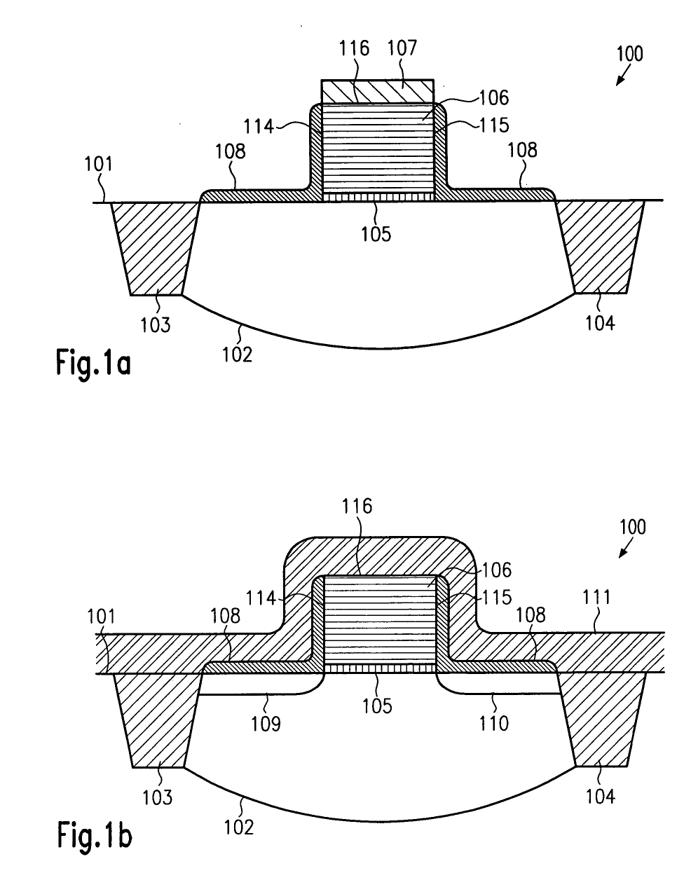

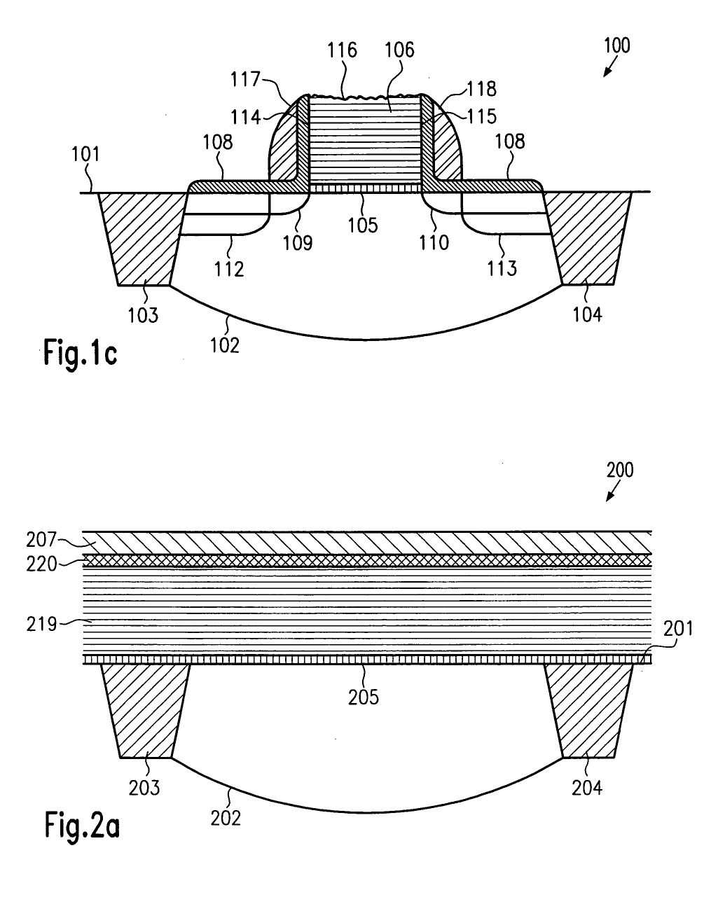

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention makes it possible to manufacture a field effect transistor, substantially without there being an erosion of the gate electrode, or at least with a significantly reduced erosion of the gate electrode in the formation of the sidewall spacers. To this end, one or more protective layers are formed both over a side surface and over a top surface of a feature on a substrate, such as a gate electrode. A layer of a spacer material is conformally deposited over the side surface, the top surface and the substrate. Subsequently, the layer of spacer material is etched anisotropically to form sidewall spacers adjacent the feature. In the etching process, the one or more protective layers may prevent or reduce the erosion of the feature.

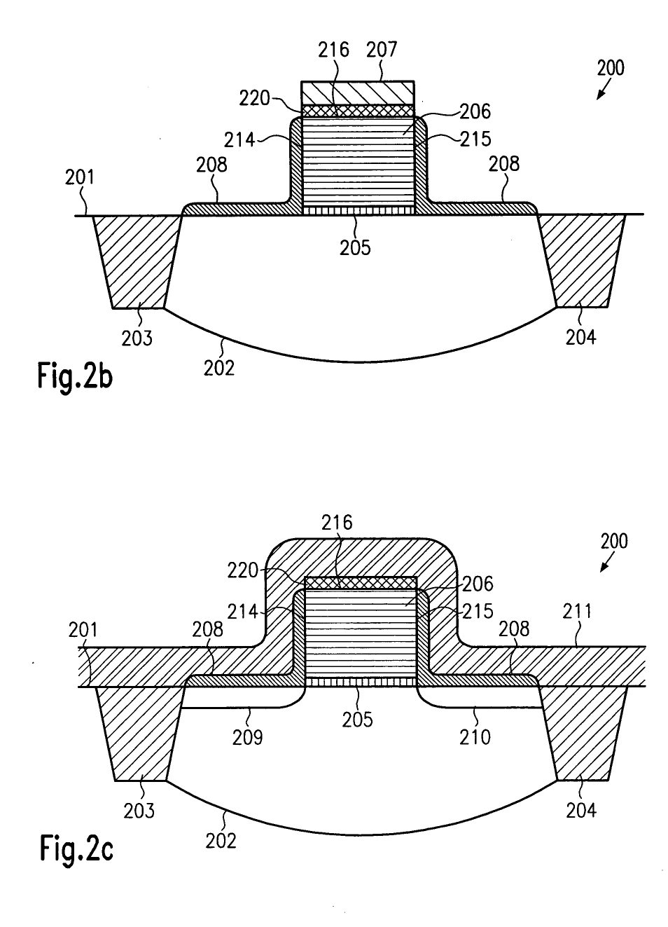

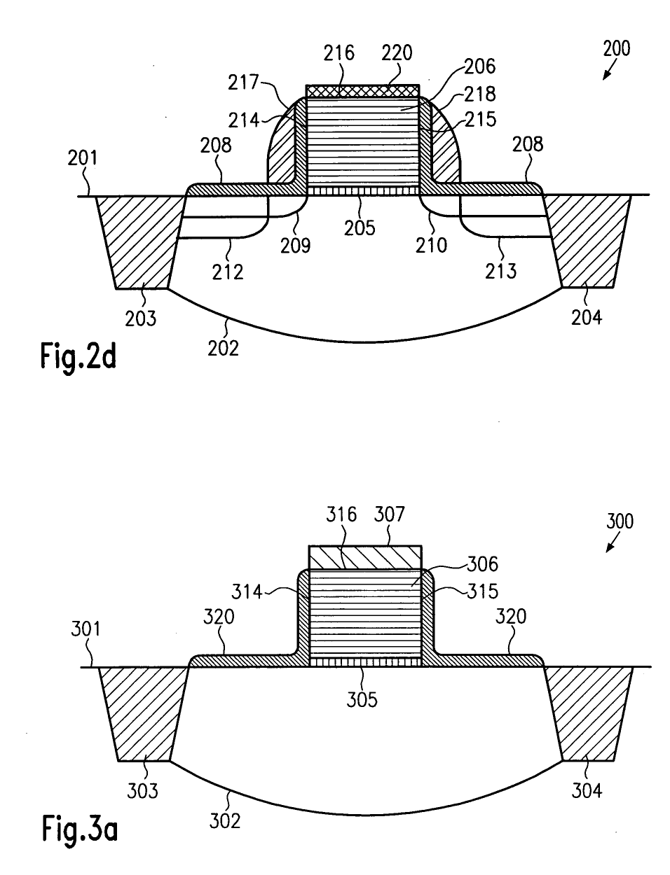

Further illustrative embodiments of the present invention are described with reference to FIGS. 2a-2d. FIG. 2a shows a schematic cross-sectional view of a field effect transistor in a first stage of the manufacturing process. In a substrate 201, an active region 202 and trench isolations 203, 204 are formed. Then, a gate insulation layer 205 is formed over the substrate 201. Subsequently, a layer 219 of a material is deposited over the substrate 201 and the gate insulation layer 205. The deposition of the layer of material 219 may be performed using deposition techniques such as physical vapor deposition, chemical vapor deposition and/or plasma enhanced chemical vapor deposition.

In physical vapor deposition, a material is transported from a source to a deposition surface via physical processes such as gas flow and diffusion. There is substantially no chemical modification of the material. The deposition surface may be, e.g., a surface of the gate insulation layer 205 or a surface of the layer 219. In the source, the material can be evaporated thermally to create a vapor of the material. The deposition surface is exposed to the vapor. The vapor condenses on the deposition surface, which leads to a growth of the layer 219. Alternatively, sputtering may be applied in physical vapor deposition. A target made of the material is bombarded with ions extracted from a plasma. This causes the ejection of atoms from the target, which are then deposited on the deposition surface.

In chemical vapor deposition, the deposited material is formed as a result of a chemical reaction between gaseous reactants, which occurs on or in the vicinity of the deposition surface. Solid products of the reaction are deposited on the deposition surface.

Plasma enhanced chemical vapor deposition is a variant of chemical vapor deposition wherein the chemical reaction occurs in a plasma, which may be created, e.g., by means of a glow discharge. Advantageously, plasma enhanced chemical vapor deposition allows the deposition of the material at a lower temperature than conventional chemical vapor deposition.

In a particular embodiment of the present invention, a material of the substrate 201 comprises crystalline silicon, the gate insulation layer 205 comprises silicon dioxide and the material of the layer 219 comprises polycrystalline silicon. In this embodiment, the deposition of the layer 219 may be accomplished by performing a chemical vapor deposition or a low pressure chemical vapor deposition process, wherein the reactant gas comprises silane (SiH₄).

Following the deposition of the layer 219, a first protective layer 220 is formed over the layer 219. In one embodiment, forming the first protective layer 220 may comprise a thermal oxidation of a portion of the layer 219. In thermal oxidation, the layer 219 is exposed to an oxidizing ambient such as oxygen or water at an elevated temperature. Thereby, a chemical reaction between the material of the layer 219 and the oxidizing ambient occurs, which leads to the formation of an oxide of the material. A thickness of the first protective layer may range from approximately 0.6-5 nm.

Thermal oxidation may be performed by means of rapid thermal oxidation. In rapid thermal oxidation, the field effect transistor 200 is heated to a high temperature for a short time while being exposed to the oxidizing ambient. This may be done, e.g., by irradiating the field effect transistor 200 with radiation from a plurality of lamps.

Alternatively, thermal oxidation may be performed by heating the field effect transistor 200 in a furnace while being exposed to the oxidizing ambient. During thermal oxidation in a furnace, temperature is typically lower than during rapid thermal oxidation. A duration of thermal oxidation in a furnace can be longer than a duration of rapid thermal oxidation.

In the thermal oxidation, a portion of the layer 219 close to a surface thereof is oxidized. Thereby, an oxide of the material of the layer 219 is created which forms the first protective layer 220. Thus, the first protective layer 220 grows at the expense of the layer 219. The material loss in the layer 219 may be taken into account by correspondingly adapting a thickness of the layer 219. If a higher temperature is applied in the thermal oxidation process, the oxidation occurs more quickly. Hence, a thickness of the first protective layer 220 may be controlled by controlling the duration of the thermal oxidation and the applied temperature. The longer the duration and the higher the applied temperature, the thicker the first protective layer 220 becomes.

Thermal oxidation may be followed by rapid thermal annealing. In rapid thermal annealing, the field effect transistor is heated to high temperature in the absence of the oxidizing ambient. A temperature applied in the rapid thermal annealing may be higher than a temperature applied in the thermal oxidation. In the annealing, a thermally activated re-arrangement of atoms in the first protective layer 220 may occur such that the first protective layer 220 is densified. Advantageously, this increases the stability of the first protective layer with respect to etching.

In other embodiments of the present invention, the formation of the first protective layer may comprise physical vapor deposition, chemical vapor deposition and/or plasma enhanced chemical vapor deposition. These processes may be followed by rapid thermal annealing to densify the first protective layer 220.

The first protective layer 220 may comprise an oxide of the material of the layer 219. In an embodiment of the present invention wherein the material of the layer 219 comprises polycrystalline silicon, the material of the layer 220 can comprise silicon dioxide (SiO₂).

After the formation of the first protective layer 220, a coating layer 207 is deposited over the first protective layer, which may be performed, e.g., by means of physical vapor deposition, chemical vapor deposition or plasma enhanced chemical vapor deposition. The coating layer 207 may be comprised of silicon nitride or silicon oxynitride, and it may have a thickness of approximately 10-60 nm. Then, the gate insulation layer 205, the layer 219, the first protective layer 220 and the coating layer 207 are patterned, which may be accomplished by performing known photolithography and etching processes.

The coating layer 207 may be configured such that, in the photolithography patterning, adverse effects resulting from an interference between incident light and light reflected from the layer 219 and the first protective layer 220 are substantially avoided. To this end, a thickness of the coating layer 207 can be adapted such that light reflected from the surface of the coating layer interferes destructively with light reflected from an interface between the coating layer 207 and the first protective layer 220 and/or an interface between the first protective layer 220 and the layer 219. Thus, a reflectivity of the layer 219 and the first protective layer 220 is effectively reduced.

In other embodiments of the present invention, an interference between incident and reflected light may substantially be avoided by forming the coating layer 207 of a material that absorbs incident light penetrating the photoresist used in photolithography. This helps avoid reflection of light by the layer 219 and the first protective layer 220. Forming the coating layer 207 of material absorbing the incident light and adapting the thickness of the coating layer 207 such that there is destructive interference between incident and reflected light may also be combined with each other.

A schematic cross-sectional view of the field effect transistor 200 in a later stage of the manufacturing process is shown in FIG. 2b. In the patterning of the gate insulation layer 205, the layer 219, the first protective layer 220 and the coating layer 207, a gate electrode 206 is formed over the substrate 201 and the gate insulation layer 205. The gate electrode 206 comprises a top surface 216, which is covered by the first protective layer 220 and the coating layer 207. Additionally, the gate electrode 206 comprises side surfaces 214, 215.

After the formation of the gate electrode 206, a second protective layer 208 is formed over the substrate 201 and the side surfaces 214, 215 of the gate electrode 206. Forming the second protective layer 208 may comprise thermal oxidation of a portion of the gate electrode 206 close to the side surfaces 214, 215, and a portion of the substrate 201 close to a surface of the substrate 201. Similar to the thermal oxidation used in the formation of one embodiment of the first protective layer 220, the thermal oxidation used in the formation of the second protective layer 208 may be performed by means of rapid thermal oxidation or by means of thermal oxidation in a furnace and can be followed by rapid thermal annealing.

In the thermal oxidation, the second protective layer 208 grows at the expense of the portions of the gate electrode 206 adjacent the side surfaces 214, 215 and a portion of the substrate 201 close to the surface of the substrate 201. The material loss in these portions may be taken into account in advance by correspondingly adapting a length of the gate electrode 206 and a depth of the active region 202.

The layer 208 may comprise an oxide of the material of the layer 219 and an oxide of the material of the substrate 201. In an embodiment of the present invention wherein the material of the substrate 201 comprises crystalline silicon and the gate electrode 206 comprises polycrystalline silicon, the layer 208 comprises silicon dioxide.

After the formation of the second protective layer 208, the coating layer 207 is removed. Removing the coating layer 207 may comprise exposing the coating layer 207 to an etchant adapted to selectively remove the material of the coating layer 207, whereas the material of the first protective layer 220 and the material of the second protective layer 208 remain substantially unaffected by the etchant. Thus, the first and the second protective layer are preserved in the removing of the coating layer 207 and protect the gate electrode 206 and the substrate 201 from being affected by the etchant.

Exposing the coating layer 207 to an etchant may comprise wet chemical etching. The wet chemical etching may comprise exposing the coating layer to hot phosphoric acid. In particular, exposing the coating layer 207 to hot phosphoric acid may be used to selectively remove the coating layer 207 in an embodiment of the present invention wherein the coating layer 207 comprises silicon nitride.

FIG. 2c shows the field effect transistor 200 in a further stage of the manufacturing process. After the removal of the coating layer 207, an extended source region 209 and an extended drain region 210 are formed in the substrate 201 adjacent the gate electrode 206. This may be done by implanting ions of a dopant material into the substrate 201. Parts of the substrate 201 that are not to be doped can be covered by a layer of photoresist (not shown) that absorbs ions.

In other embodiments of the present invention, the formation of the extended source region 209 and the extended drain region 210 may be performed before the removing of the coating layer 207. Thus, in the ion implantation, the coating layer 207 absorbs ions directed to the field effect transistor 200, such that an irradiation of the gate electrode 206 and the gate insulation layer 205 with energetic ions is advantageously avoided.

In further embodiments of the present invention, the formation of the extended source region 209 and the extended drain region 210 may be performed before the formation of the second protective layer 208.

A layer of a spacer material 211 is conformally deposited over the substrate 201, the top surface 216 and the side surfaces 214, 215. Due to the conformal deposition, a thickness of portions of the layer 211 over the top surface 216, over the side surfaces 214, 215, and over the substrate 201 is substantially equal. The conformal deposition of the layer of spacer material 211 may be performed by means of physical vapor deposition, chemical vapor deposition or plasma enhanced chemical vapor deposition. In one illustrative embodiment, the spacer material may comprise silicon nitride.

A schematic cross-sectional view of the field effect transistor 200 after the completion of the manufacturing process is shown in FIG. 2d. After the deposition of the layer of spacer material 211, this layer is etched anisotropically. An etchant used in the anisotropic etching is adapted such that the spacer material is selectively removed, whereas the first protective layer 220 and the second protective layer 208 remain substantially unaffected by the etchant.

The anisotropic etching of the layer of spacer material 211 may comprise dry etching. Due to the anisotropy of the etching process, portions of the layer of spacer material 211 that are substantially horizontal, such as the portion over the top surface 216 and the portion over the surface of the substrate 201, are removed more quickly than portions of the layer of spacer material 211 which are substantially vertical, such as portions over the side surfaces 214, 215. Thus, sidewall spacers 217, 218 similar to the sidewall spacers 117, 118 in the field effect transistor 100 according to the state of the art are formed adjacent the gate electrode.

Since the first protective layer 220 and the second protective layer 208 remain substantially unaffected by the etchant, they protect the substrate 201 and the gate electrode 206 from being exposed to the etchant. Thus, an erosion of the gate electrode 206 is advantageously avoided or reduced.

After the formation of the sidewall spacers 217, 218, a source region 212 and a drain region 213 are formed in the substrate 201 by implanting ions of a dopant material into the substrate 201. In the ion implantation, the sidewall spacer 217 absorbs ions such that the source region 212 is spaced apart from the gate electrode 206. Similarly, the drain region 213 is spaced apart from the gate electrode 206, since the sidewall spacer 218 absorbs ions.

Finally, an annealing step may be performed to activate dopants in the active region 202, the source region 212, the extended source region 209, the drain region 213 and the extended drain region 210.

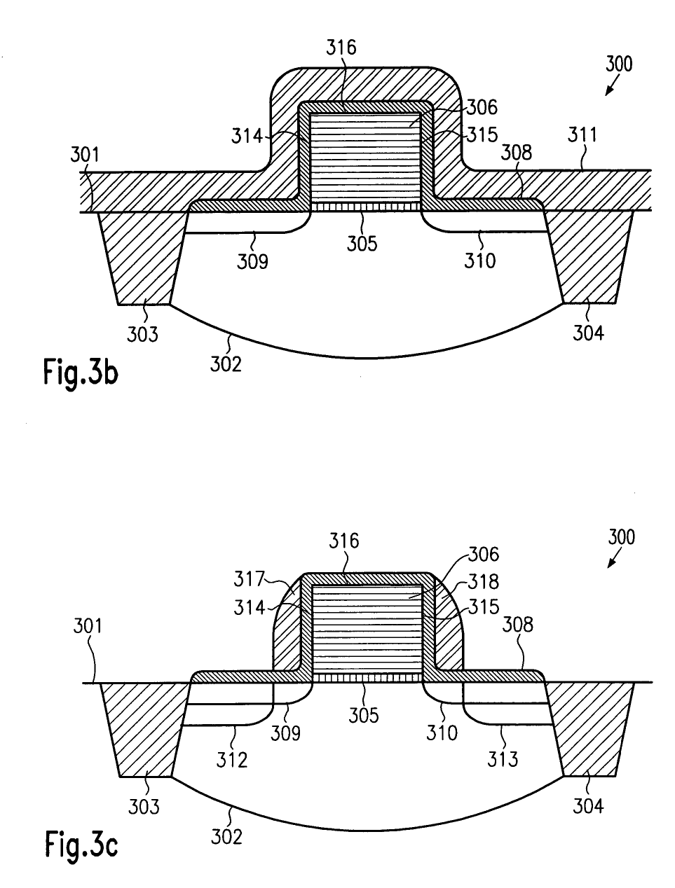

Further embodiments of the present invention are described with reference to FIGS. 3a-3c. FIG. 3a shows a field effect transistor 300 in a first stage of a manufacturing process according to an embodiment of the present invention. In a substrate 301, an active region 302 and trench isolations 303, 304 are formed. These features may be formed using advanced techniques of ion implantation, deposition, oxidation and photolithography.

A gate electrode 306 having side surfaces 314, 315 and a top surface 316, the top surface being covered by a coating layer 307, is formed over a gate insulation layer 305 and the substrate 301. This may be done as follows. First, the gate insulation layer 305 is deposited over the substrate 301. Then, a layer of a gate electrode material similar to the layer 219 shown in FIG. 2a is deposited over the gate insulation layer 305 and the substrate 301. The coating layer 307 is deposited over the layer of the gate electrode material. Subsequently, the gate insulation layer 305, the layer of the gate electrode material and the coating layer 307 are patterned to form the gate electrode 306. This may be done by performing photolithography and etching techniques. Similar to the coating layer 207 in the embodiment of the present invention described with reference to FIGS. 2a-2d, the coating layer 307 may be configured such that, in photolithography, adverse effects resulting from an interference between incident light and reflected light are substantially avoided.

A material of the substrate 301 may comprise silicon. The gate insulation layer 305 may comprise silicon dioxide. The layer of the material may comprise polycrystalline silicon and a material of the coating layer 307 may comprise silicon nitride.

A first protective layer 320 is formed over the side surfaces 314, 315 of the gate electrode 306 and over the substrate 301. Similar to the formation of the first protective layer 220 and the second protective layer 208 in the embodiment of the present invention described with reference to FIGS. 2a-2d, the formation of the first protective layer 320 can comprise thermal oxidation of portions of the gate electrode 306 close to the side surfaces 314, 315, and a portion of the substrate 301 close to a surface of the substrate 301. The thermal oxidation can be performed in a furnace or by means of rapid thermal oxidation, and may be followed by rapid thermal annealing.

In one illustrative embodiment, a material of the first protective layer 320 may comprise an oxide of a material of the gate electrode 306 and an oxide of the material of the substrate 301. In an embodiment of the present invention wherein the gate electrode 306 comprises polycrystalline silicon and the material of the substrate 301 comprises crystalline silicon, the first protective layer 320 may comprise silicon dioxide.

Subsequently, the coating layer 307 is removed, which may be done by exposing the coating layer 307 to an etchant adapted to selectively remove the material of the coating layer 307, whereas a material of the first protective layer is substantially not affected by the etchant.

Similar to the removing of the coating layer 207 in the embodiment of the present invention described with reference to FIGS. 2a-2d, the removing of the coating layer 307 may comprise wet chemical etching, which may comprise exposing the coating layer 307 to phosphoric acid. Advantageously, wet chemical etching may provide a high selectivity of the etching of the material of the coating layer 307, such that the gate electrode 306 is substantially not damaged by the etching process, or there is at most low damage of the gate electrode.

After the removal of the coating layer 307, the first protective layer 320 can be removed. This may be done by means of exposing the first protective layer 320 to an etchant adapted to selectively remove the material of the first protective layer 320, whereas the material of the gate electrode 306 and the material of the substrate 301 are substantially not affected by the etchant.

The removing of the first protective layer 320 may be performed by means of wet chemical etching. In an embodiment of the present invention wherein the first protective layer 320 comprises silicon dioxide, this may be done by dipping the field effect transistor 300 into an aqueous solution of hydrofluoric acid (HF). Advantageously, wet chemical etching allows a particularly high selectivity of the etching process, such that there is substantially no damaging of the gate electrode or at most low damage of the gate electrode.

FIG. 3b shows the field effect transistor 300 in a later stage of the manufacturing process. A second protective layer 308 is formed over the side surfaces 314, 315 of the gate electrode 306, the top surface 316 of the gate electrode 306 and the surface of the substrate 301. This may be done by means of thermal oxidation or by means of physical vapor deposition, chemical vapor deposition and/or plasma enhanced chemical vapor deposition. The formation of the second protective layer may be followed by rapid thermal annealing to densify the second protective layer 308. A material of the second protective layer may comprise silicon dioxide.

In other embodiments of the present invention, the first protective layer 320 is not removed before the formation of the second protective layer 308. Instead, the first protective layer 320 remains on the side surfaces of the gate electrode 306 and the surface of the substrate 301, and is covered by the second protective layer 308 and/or incorporated into the second protective layer 308. Advantageously, this allows reduction of the production costs of the field effect transistor 300, since the exposing of the first protective layer 320 to the etchant can be omitted.

An extended source region 309 and an extended drain region 310 are formed in the substrate 301 adjacent the gate electrode 306. This may be done by implanting ions of a dopant material into the substrate 301. Portions of the substrate 301 outside the field effect transistor 300 that are not to be doped can be covered by a layer of photoresist (not shown) that absorbs ions.

In other embodiments of the present invention, the formation of the extended source region 309 and the extended drain region 310 can be performed before the formation of the first protective layer 320, before the removing of the first protective layer 320 or before the formation of the second protective layer 308.

Similar to the embodiment of the present invention described with reference to FIGS. 2a-2c, a layer of a spacer material 311 is deposited conformally over the side surfaces 314, 315 of the gate electrode 316, the top surface 316 of the gate electrode 306 and the substrate 301. The layer of spacer material 311 is etched anisotropically to form sidewall spacers 317, 318, as shown in FIG. 3c.

The anisotropic etching of the layer of spacer material 311 may comprise exposing the layer of spacer material 311 to an etchant adapted to selectively remove the spacer material, whereas the material of the second protective layer 308 is substantially not affected by the etchant. Thus, the second protective layer 308 protects the gate electrode 306 and the substrate 301 from being exposed to the etchant, such that an undesirable erosion of the gate electrode 306 and the substrate 301 is advantageously avoided or reduced.

After the formation of the sidewall spacers 317, 318, a source region 312 and a drain region 313 are formed in the substrate 301. This may be done by implanting ions of a dopant material into the substrate. Since the sidewall spacers 317, 318 absorb ions, the source region 312 and the drain region 373 are spaced apart from the gate electrode 306.

Finally, the field effect transistor 300 may be completed by performing an annealing step to activate dopants in the active region 302, the source region 312, the drain region 313, the extended source region 309 and the extended drain region 310.

The present invention is not restricted to the formation of field effect transistors. Instead, the present invention may be applied quite generally to the formation of sidewall spacers adjacent a feature on a substrate. For example, the present invention may be applied to the formation of electrically conductive lines.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method of forming sidewall spacers, comprising:
forming a feature over a substrate, said feature having a side surface and a top surface, said top surface being covered by a first protective layer and a coating layer formed above said first protective layer;
forming a second protective layer over said side surface and said substrate;
removing said coating layer;
conformally depositing a layer of a spacer material over said substrate and said side surface and above said top surface; and
anisotropically etching said layer of spacer material.

2. The method of claim 1, wherein said forming said feature comprises:
depositing a layer of a material over said substrate;
forming said first protective layer over said layer of material;
depositing said coating layer over said first protective layer; and
patterning said layer of material, said first protective layer and said coating layer.

3. The method of claim 2, wherein said material comprises polycrystalline silicon.

4. The method of claim 2, wherein forming said first protective layer comprises performing a thermal oxidation process of a portion of said layer of material.

5. The method of claim 4, wherein forming said first protective layer further comprises performing a rapid thermal annealing process.

6. The method of claim 2, wherein forming said first protective layer comprises performing at least one of a physical vapor deposition, a chemical vapor deposition and a plasma enhanced chemical vapor deposition process.

7. The method of claim 1, wherein said feature comprises a gate electrode.

8. The method of claim 1, wherein at least one of said first protective layer and said second protective layer is comprised of silicon dioxide.

9. The method of claim 1, wherein said coating layer comprises silicon nitride.

10. The method of claim 1, wherein said spacer material comprises silicon nitride.

11. The method of claim 1, wherein forming said second protective layer comprises performing a thermal oxidation process of a portion of said feature and a portion of said substrate.

12. The method of claim 11, wherein forming said second protective layer further comprises performing a rapid thermal annealing process.

13. The method of claim 1, wherein removing said coating layer comprises performing a wet chemical etching process.

14. The method of claim 13, wherein performing said wet chemical etching process comprises exposing said coating layer to phosphoric acid.

15. The method of claim 1, wherein removing said coating layer comprises performing a dry etching process.

16. The method of claim 1, wherein said conformal deposition of the layer of spacer material comprises performing at least one of a physical vapor deposition, a chemical vapor deposition and a plasma enhanced chemical vapor deposition process.

17. The method of claim 1, wherein said anisotropic etching of the layer of spacer material comprises performing a dry etching process.

18. A method of forming sidewall spacers, comprising:
forming a feature over a substrate, said feature having a side surface and a top surface, said top surface being covered by a coating layer;
forming a first protective layer over said side surface and said substrate;
removing said coating layer;
forming a second protective layer over said side surface, said top surface and said substrate;
conformally depositing a layer of a spacer material over said side surface, said top surface and said substrate; and
anisotropically etching said layer of spacer material.

19. The method of claim 18, wherein forming said feature comprises:
depositing a layer of a material over said substrate;
depositing said coating layer over said layer of material; and
patterning said layer of material and said coating layer.

20. The method of claim 19, wherein said material comprises polycrystalline silicon.

21. The method of claim 18, further comprising removing said first protective layer, wherein removing said first protective layer is performed after removing said coating layer.

22. The method of claim 18, wherein said feature comprises a gate electrode.

23. The method of claim 18, wherein at least one of said first protective layer and said second protective layer comprise silicon oxide.

24. The method of claim 18, wherein said coating layer comprises silicon nitride.

25. The method of claim 18, wherein said spacer material comprises silicon nitride.

26. The method of claim 18, wherein forming said first protective layer comprises performing a thermal oxidation process of a portion of said feature and a portion of said substrate.

27. The method of claim 26, wherein forming said first protective layer further comprises performing a rapid thermal annealing process.

28. The method of claim 18, wherein forming said second protective layer comprises performing a thermal oxidation process of a portion of said feature and a portion of said substrate.

29. The method of claim 28, wherein forming said second protective layer further comprises performing a rapid thermal annealing process.

30. The method of claim 18, wherein forming said second protective layer comprises performing a chemical vapor deposition process.

31. The method of claim 18, wherein removing said coating layer comprises performing a wet chemical etching process.

32. The method of claim 31, wherein said wet chemical etching comprises exposing said coating layer to phosphoric acid.

33. The method of claim 18, wherein said conformal deposition of the layer of spacer material comprises performing at least one of a physical vapor deposition, a chemical vapor deposition and a plasma enhanced chemical vapor deposition process.

34. The method of claim 18, wherein said anisotropic etching of the layer of spacer material comprises performing a dry etching process.
